(19) United States
(12) Patent Application Publication
(10) Pub. No.: US 2009/0057811 A1
(43) Pub. Date: Mar. 5, 2009

(54) SIMOX WAFER MANUFACTURING METHOD AND SIMOX WAFER

(75) Inventors: Yoshio MURAKAMI, Tokyo (JP); Kenji OKITA, Tokyo (JP); Tomoyuki HORA, Tokyo (JP)

Correspondence Address: GREENBLUM & BERNSTEIN, P.L.C., 1950 ROLAND CLARKE PLACE, RESTON, VA, 20191, US

(73) Assignee: SUMCO CORPORATION, Tokyo (JP)

(21) Appl. No.: 12/199,040

(22) Filed: Aug. 27, 2008

(30) Foreign Application Priority Data
Aug. 28, 2007 (JP) 2007-220943

(51) Int. Cl. H01L 29/00; H01L 21/762

(52) U.S. Cl. 257/506; 438/407; 257/E21.561; 257/E29.001

(57) ABSTRACT

A SIMOX wafer manufacturing method which is capable of providing etching conditions to prevent surface defects (divots) from being spread. The method includes an oxygen implantation process and a high temperature annealing step for forming a BOX layer, a front surface oxide film etching process to treat a front surface of the wafer at an area in which oxygen is implanted, and a rear surface oxide film etching process to treat a rear surface of the wafer, and oxide film etching conditions in the front and rear oxide film etching processes are controlled differently.

### BACKGROUND OF THE INVENTION

1. Field of the Invention

The present invention relates to a SIMOX (Silicon Implantation of Oxygen) wafer manufacturing method and a SIMOX wafer, and more particularly, to a technique adaptable for a SIMOX wafer, which is currently being produced and used in large quantities, as well as an attachment type SOI, as a thin film SOI (Silicon on Insulator) wafer having a buried oxide film for forming a high speed and low power-consuming SOI device.

Priority is claimed on Japanese Patent Application No. 2007-220943, filed Aug. 28, 2007, the content of which is incorporated herein by reference.

2. Description of Related Art

A SIMOX wafer has been known as disclosed in Japanese Patent Publication Nos. 2004-200291, 2006-351632 and 2007-5563 and has excellent film thickness uniformity of a SOI layer.

In the SIMOX wafer, the SOI layer can be formed at a thickness of 0.4 μm or less, possibly up to about 0.1 μm or even below. In particular, a SOI layer having a thickness of 0.02 μm or less is being widely used to form a fully depletion type MOS-LSI. In this case, since the thickness of the SOI layer is proportional to a threshold voltage of MOSFET operation, uniformity of thickness of the SOI layer is a factor important in manufacturing a high performance device with a high yield. From this standpoint, a SIMOX wafer having excellent thickness uniformity of the SOI layer is being expected as a substrate for the next generation of MOSFETs.

A SIMOX wafer has been conventionally known to include two kinds of SIMOXs, i.e., a high dose SIMOX having a high oxygen implantation dose and a low dose SIMOX which has an oxygen implantation dose lower by one digit than the high oxygen implantation dose and is used to form a buried oxide film using an ITOX (Internal Oxidation) technique, which performs an annealing process thereafter under a high oxygen atmosphere. In addition, in recent years, an MLD (Modified Low Dose) method has been developed which allows the formation of an amorphous layer in a low dose SIMOX by performing a last implantation process with a small dose at around room temperature and forming a BOX at a lower dose for mass production.

A high dose SIMOX is typically subjected to a process in which O⁺ ions are implanted at an implantation energy of 150 Kev, implantation dose of 1.5×10¹⁸ cm⁻² or more, and substrate temperature of 500° C., and annealing is performed at 1300° C. or above for 4 to 8 hours under an argon or nitrogen atmosphere including oxygen of 0.5 to 2%.

This process has problems of having a very long implantation time, poor throughput, a very high SOI layer dislocation density of 1×10⁵ cm⁻² to 1×10¹⁷ cm⁻², etc (see K. Izumi et al. Electron. Lett. (UK) vol. 14 (1978) P593).

For the purpose of overcoming these problems, a low dose SIMOX is typically subjected to a process in which an implantation is performed at an implantation energy of 150 Kev or above, an implantation dose of 4×10¹⁷ cm⁻² to 1×10¹⁷ cm⁻², and a substrate temperature of 400° C. to 600° C., and annealing is performed at 1300° C. or above under an argon atmosphere including oxygen of 30 to 60%, thereby making a BOX layer thick by internal oxidation (ITOX) using oxygen in annealing and thus achieving significant improvement of quality (see S. Nakashima et al. Proc. IEEE int. SOI Conf. (1994) P71-2).

In addition, as an improvement version of low dose SIMOX, there has been proposed an MLD (Modified Low Dose) method in which an implantation is performed at a room temperature at a dose lower by one digit than the dose in the low dose SIMOX to form an amorphous layer on a surface after a conventional process of implanting oxygen at a high temperature (400° C. to 650° C.).

According to this method, continuous BOX growth becomes possible from a wide low dose range of 1.5×10¹⁷ cm⁻² to 6×10¹⁷ cm⁻², and also internal oxidation becomes possible at 1.5 times the speed of the conventional ITOX in a subsequent ITOX process. As a result, a BOX oxide film (BOX layer) becomes very close to a thermal oxide film, thereby significantly improving quality.

Typically, in the MLD process, it is common to perform annealing for 5 to 10 hours under an argon atmosphere including oxygen of 0.5 to 2% after the ITOX process in order to lower the amount of oxygen in an SOI layer (see O. W. Holland et al. Appl. Phys. Lett. (USA) vol. 69 (1996) P574 and U.S. Pat. No. 5,930,643).

In other words, as shown in FIG. 3, a MLD-SIMOX wafer is conventionally manufactured through an oxygen implantation process (S01), an HF etching process (SO2), a cleaning process (SO3), a high temperature annealing process (S04), an oxide film etching process (SO5), a SOI layer thickness measuring process (S07) and a cleaning process (S08).

The high temperature annealing process (S04) of the SOI wafer is performed at a temperature of 1300° C. or above for 10 hours or more under an argon atmosphere including oxygen. In addition, a vertical furnace is typically used to suppress slips.

An annealing furnace used in the high temperature annealing process (S04) has high cleanness by sufficiently cleaning and heating the annealing furnace before being used, however, with an increase in the number of times of annealing, this annealing furnace has a problem of unavoidable attachment of particles from a tube, a boat, a jig and so on. In addition, since a rear side of the annealing furnace contacts a holder, now a few particles are attached to the rear side and the particles in contact with the holder are as large as 1 μm to 5 μm or above, which is known to be relatively large. Accordingly, particles attached to a wafer are simultaneously removed in the oxide film etching process (S05).

While an oxide film formed in the high temperature annealing process (S04) is removed in the oxide film etching process (S05), the oxide film etching process (S05) treats front and rear surfaces of the wafer simultaneously under a conventional over etch condition of 20% in terms of an HF-based etchant. However, in the conventional condition, even when the oxide film at the rear surface of the wafer is sufficiently etched, there is a problem of insufficient removal of particles from the front surface of the wafer.

In addition, in the above conventional condition, the oxide film etching process (S05) has a problem of insufficient etching of oxide film in the rear surface of the wafer.

In order to overcome these problems, although etching is performed with strict conditions of long time and high concentration HF so as to remove particles on the front and rear surfaces, there arises an additional problem of significant increase size of not a few surface defects (divots) on the SOI wafer due to the long HF etching time.

In addition, since the surface defects of the increased size reach from the wafer surface to a BOX layer in its depth direction, the BOX layer is melted by the HF etching of the strict conditions, which results in a further increase of the defect size and, in the worst case, a useless SIMOX wafer.

In consideration of the above circumstances, it is an object of the invention to provide a method of manufacturing a SIMOX wafer, which is capable of providing optimal etching conditions to allow fully removing particles of a rear surface of the wafer and preventing surface defects (divots) on the wafer from being spread in an oxide film etching process after high temperature annealing in manufacturing the SIMOX wafer, such that both of the front and rear surfaces of the wafer have few particles of 0.1 μm to 5 μm, the size of surface defects (divots) is 1 μm or less, and the number of surface defects is 10 or less.

### SUMMARY OF THE INVENTION

To accomplish the above object, according to an aspect of the invention, a method of manufacturing a SIMOX wafer is provided. The method includes an oxygen implantation step and a high temperature annealing step for forming a BOX layer, and an oxide film etching step after the high temperature annealing step, wherein the oxide film etching step includes a front surface oxide film etching step to treat a front surface of the wafer at an area in which oxygen is implanted and a rear surface oxide film etching step to treat a rear surface of the wafer, and wherein oxide film etching conditions in the front and rear oxide film etching steps are controlled differently.

Preferably, in the present invention, the oxide film etching step is performed with an HF-based etchant and adjusts etching time, etching temperature and etchant concentration for the front and rear surfaces independently.

Preferably, in the oxide film etching step of the present invention, the oxide film etching conditions of the front surface oxide film etching step can be set less strictly than the oxide film etching conditions of the rear surface oxide film etching step.

Preferably, in the present invention, in the oxide film etching step, the front surface oxide film etching step is performed after the rear surface oxide film etching step, and the rear surface oxide film etching step can be performed with single wafer etching to treat only the rear surface of the wafer.

Preferably, the front surface oxide film etching step treats only the front surface of the wafer or both of the front and rear surfaces of the wafer.

Preferably, in the present invention, in the oxide film etching step, scrub cleaning or ultrasonic cleaning is used to increase removal efficiency of particles in addition to the HF etching.

Preferably, in the rear surface oxide film etching step, the front surface of the wafer can be protected from the etchant by ejecting air, nitrogen (N₂) or pure water on the front surface.

Preferably, in the rear surface oxide film etching step, the single wafer etching is performed by ejecting the etchant from a nozzle on the rear surface of the wafer rotated around the center of the wafer.

According to another aspect of the present invention, there is provided a SIMOX wafer manufactured using one of above-described manufacturing methods.

In the method of manufacturing a SIMOX wafer of the present invention, the method includes an oxygen implantation step and a high temperature annealing step for forming a BOX layer, and an oxide film etching step after the high temperature annealing step, since the oxide film etching step includes a front surface oxide film etching step to treat a front surface of the wafer at an area in which oxygen is implanted and a rear surface oxide film etching step to treat a rear surface of the wafer, and oxide film etching conditions in the front and rear oxide film etching steps are controlled differently, the oxide film etching conditions in the front and rear surfaces can be independently optimized in the oxide film etching step after the high temperature annealing step, which may result in a reduction of particles of the front and rear surfaces of the SOI wafer.

In the present invention, since the oxide film etching step is performed with an HF-based etchant and adjusts etching time, etching temperature, and etchant concentration for the front and rear surfaces independently, the front and rear surfaces, which are required to be treated differently in the oxide film etching step as the front and rear surfaces have different conditions on particles and surface defects (divots), can be treated with corresponding oxide film etching conditions, thereby making it possible to manufacture a SIMOX wafer with its front and rear surfaces having few particles and with little increase of size of surface defects.

In the oxide film etching step of the present invention, since the oxide film etching conditions of the front surface oxide film etching step are set less strictly than the oxide film etching conditions of the rear surface oxide film etching step, it is possible to fully etch off oxide films of the front and rear surfaces, fully remove surface particles and prevent surface defects (divots) from being spread, thereby making it possible to provide a SIMOX wafer having proper characteristics.

Specifically, the rear surface oxide film etching step is performed under oxide film etching conditions of 40 to 60% HF, preferably 49% HF, 40 to 70° C., preferably 60° C., and 3 to 5 min, preferably 3 min, while the front surface oxide film etching step is performed under oxide film etching conditions of 20 to 49% HF, preferably 49% HF, 25 to 70° C., preferably 60° C., and 0.5 to 30 min, preferably 1 min. In the preferable case, throughput can be given to priority. In particular, it is preferable that, in regard to the etchant concentration, the oxide film etching conditions in the front surface oxide film etching step be set less strictly than the oxide film etching conditions in the rear surface oxide film etching step. It is preferable that, in regard to the treatment temperature, the oxide film etching conditions in the front surface oxide film etching step be set less strictly than the oxide film etching conditions in the rear surface oxide film etching step.

In the oxide film etching step of the present invention, since the front surface oxide film etching step is performed after the rear surface oxide film etching step, and the rear surface oxide film etching step is performed with single wafer etching to treat only the rear surface of the wafer, an adverse effect of the etchant on the wafer front surface in the rear surface oxide film etching step is reduced, and thus the oxide film etching and particle removal for the wafer front surface, which is greatly affected by the etchant, can be suitably performed in the front surface oxide film etching step, and it becomes possible to etch off the oxide film by etching the wafer front surface according to optimal etching conditions to prevent surface defects (divots) from being spread.

In addition, since the front surface oxide film etching step treats only the front surface of the wafer or both of the front and rear surfaces of the wafer, an adverse effect of the etchant on the wafer front surface in the rear surface oxide film etching step is reduced, and thus the oxide film etching and particle removal for the wafer front surface, which is greatly affected by the etchant, can be suitably performed in the front surface oxide film etching step. Also, it becomes possible to etch off the oxide film by etching the wafer front surface according to the optimal etching conditions to prevent surface defects (divots) from being spread. This is because there is no problem even if the wafer rear surface is additionally etched simultaneously with the wafer front surface in the front surface oxide film etching step although only the wafer front surface may be treated like the rear surface oxide film etching step.

In the oxide film etching step of the present invention, since scrub cleaning or ultrasonic cleaning is used to increase removal efficiency of particles in addition to the HF etching, it is possible to efficiently remove oxide particles having a maximum size of 5 μm which are likely to be attached to the wafer rear surface in contact with the holder of an annealing apparatus in the high temperature annealing step, and it is possible to reliably remove particles from the wafer front surface with etching conditions to prevent surface defects (divots) from being spread.

In addition, in the rear surface oxide film etching step, an adverse effect of the etchant on the wafer front surface in the rear surface oxide film etching step is prevented since the front surface of the wafer is protected from the etchant by ejecting air, nitrogen (N₂) or pure water on the front surface. Thus, only the rear surface can be reliably treated and it becomes possible to perform the optimal etching treatment to prevent surface defects (divots) from being spread in the front surface oxide film etching step.

In addition, in the rear surface oxide film etching step, the rear surface oxide film etching step can be first performed using a batch type single wafer single-sided etching apparatus, and then the front surface oxide film etching step can be performed using a single wafer single-sided or double-sided etching apparatus since the single wafer etching is performed by ejecting the etchant from a nozzle on the rear surface of the wafer rotated around the center of the wafer. Thereby, it is possible to treat one of the wafer front and rear surfaces without any effect of the etchant on the other of wafer front and rear surface, and it is possible to precisely control throughput such as an etching margin in the oxide film etching.

Here, the single wafer etching includes the following methods performed by the following apparatus.

(1) A single wafer etching method of etching at least one surface of a wafer obtained by slicing a semiconductor ingot, wherein an etching margin at each point in a plane of the wafer surface is controlled by ejecting an etching solution on the wafer surface in rotation and controlling the flow speed and flux of the etching solution at each point in the plane of the wafer surface.

(2) The single wafer etching method according to the above item (1), wherein the flow speed and flux of the etching solution at each point in the plane of the wafer surface is controlled by controlling one or more of the rotation state of the wafer, the composition of the etching solution, the viscosity of the etching solution, the ejection state of the etching solution, the ejection position and movement state of the ejection position of the etching solution, the ejection time of the etching solution, and the diameter of the wafer.

(3) The single wafer etching method according to the above items (1) or (2), wherein the etching solution is an acid etching solution.

(4) A single wafer etching apparatus for performing a single wafer etching method according to any one of the above items (1) to (3), including:

wafer rotating means,

etching solution supplying means that supplies the etching solution,

a nozzle that ejects the etching solution on the wafer, and

ejection control means that controls an ejection state of the etching solution from the nozzle.

(5) The single wafer etching apparatus according to the above item (4), wherein the ejection control means includes nozzle position control means that set the ejection position of the etching solution from the nozzle with respect to the wafer.

(6) The single wafer etching apparatus according to the above item (4), wherein the ejection control means includes ejection state control means that sets the ejection state of the etching solution from the nozzle with respect to predetermined points on the wafer surface.

(7) A semiconductor wafer which is surface-treated by a single wafer etching method according to any one of the above items (1) to (3) or a single wafer etching apparatus according to any one of the above items (4) to (6).

Preferably, the SIMOX wafer of the present invention is manufactured by one of the above-described manufacturing methods.

According to the present invention, since the oxide film etching conditions in the front and rear surface oxide film etching steps can be controlled differently, the oxide film etching conditions in the front and rear surfaces can be independently optimized in the oxide film etching step after the high temperature annealing step, which may result in a reduction of particles of the front and rear surfaces of the SOI wafer.

### BRIEF DESCRIPTION OF THE DRAWINGS

FIG. 1 is a flow chart illustrating a method of manufacturing a SIMOX wafer according to an embodiment of the present invention.

FIGS. 2A to 2D are side sectional views showing a wafer in a process of manufacturing a SIMOX wafer according to an embodiment of the present invention.

FIG. 3 is a flow chart illustrating a conventional SIMOX wafer manufacturing method.

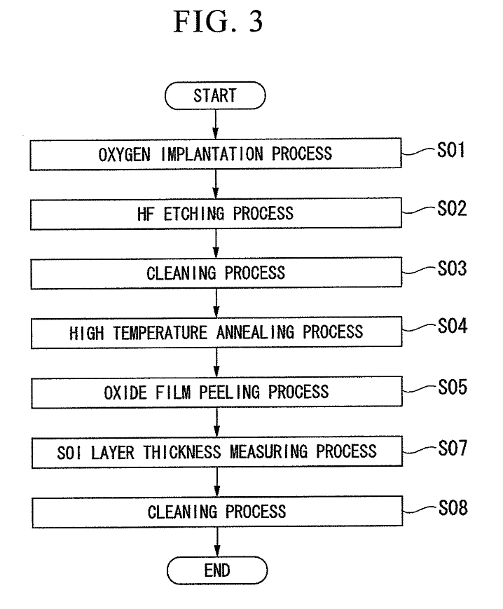

FIG. 4 is a table showing results of an embodiment of the present invention.

FIG. 5 is a schematic view showing a single wafer etching apparatus to perform a etching operation in a rear surface oxide film etching process according to an embodiment of the present invention.

### DETAILED DESCRIPTION OF THE INVENTION

While preferred embodiments of the invention will be described and illustrated below, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

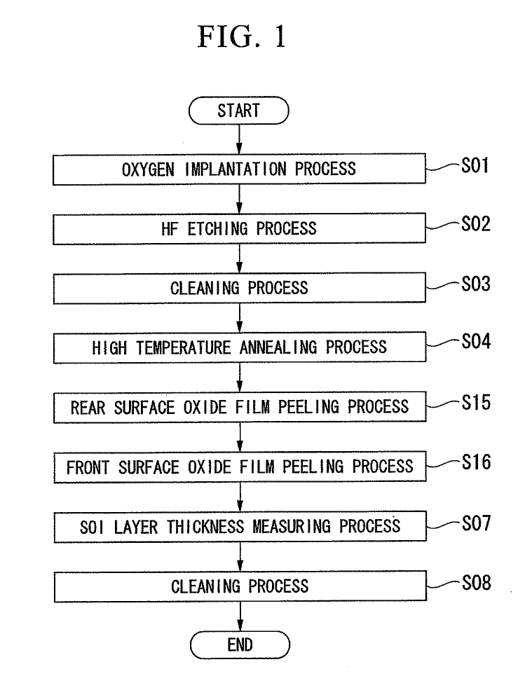

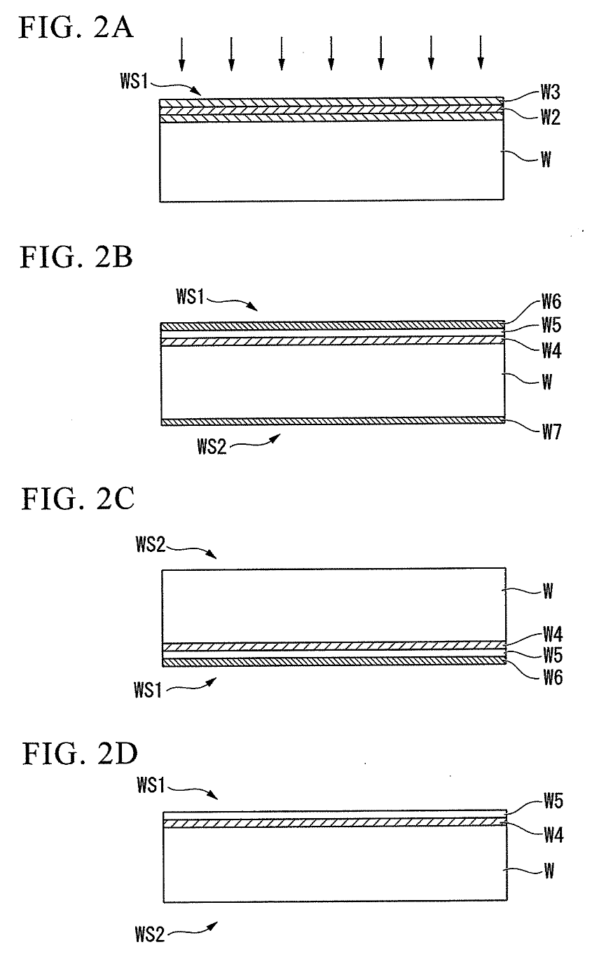

Hereinafter, an exemplary embodiment of the present invention will be described with respect to the drawings. FIG. 1 is a flow chart illustrating a method of manufacturing a SIMOX wafer according to an embodiment of the present invention, and FIGS. 2A to 2D are side sectional views showing a wafer during the process of manufacturing a SIMOX wafer. In FIGS. 2A to 2D, reference symbol W denotes a silicon wafer (SIMOX wafer).

In this embodiment, as shown in FIG. 1, the SIMOX wafer manufacturing method includes an oxygen implantation process (S01), an HF etching process (S02), a cleaning process (S03), a high temperature annealing process (S04), a rear surface oxide film etching process (S15), a front surface oxide film etching process (S16), an SOI layer thickness measuring process (S07) and a cleaning process (S08).

In the oxygen implantation process (S01), as shown in FIG. 2A, a high concentration oxygen layer W2 and an amorphous layer W3 are formed by implanting oxygen ions into a silicon wafer W. At this time, the oxygen ions are implanted in two phases, i.e., for example, a first implantation phase in which the silicon wafer W is heated at a high temperature of 300° C. or above, preferably 400° C. to 650° C., and oxygen ions are implanted with oxygen implantation energy of 140 to 220 keV, preferably 170 KeV, and a dose of 2×10¹⁶ cm⁻² to 4×10¹⁷ cm⁻², preferably 2.5×10¹⁷ cm⁻², and a second implantation phase in which oxygen ions are implanted at a room temperature with oxygen implantation energy of 140 to 220 keV, preferably 160 KeV, and a dose of 1×10¹⁴ cm⁻² to 5×10¹⁶ cm⁻², preferably 2×10¹⁵ cm⁻². The oxygen ions are implanted from a surface WS1 of the silicon wafer 1 to form the high concentration oxygen layer W2 in a region a little going into the surface WS1.

FIG. 2A shows a section of the silicon wafer W after the oxygen ions are implanted therein, where arrows schematically show implantation of the oxygen ions. First time oxygen ion implantation heats the silicon wafer W at a relatively high temperature to form the high concentration oxygen layer W2 in a state where the surface WS1 of the silicon wafer W is maintained in a single crystal, and second time oxygen ion implantation forms the amorphous layer W3 at a temperature lower than the temperature for the first time oxygen ion implantation.

Next, in the HF etching process (S02), the oxygen-implanted silicon wafer W is subjected to surface treatment under treatment conditions of an etchant of HF, at a concentration of 1 to 5%, a treatment temperature of 10 to 20° C., and a treatment time of 1 to 5 min.

Thereafter, in the cleaning process (S03), the silicon wafer W is cleaned in a temperature range of 40 to 85° C. using a cleaning method such as an SC-1 cleaning method (cleaning by a mixture of NH₄OH/H₂O₂/H₂O with a ratio of 1:1:10), an SC-2 cleaning method (cleaning by a mixture of HCl/H₂O₂/H₂O), a sulphuric acid/hydrogen peroxide cleaning method (cleaning by a mixture of H₂SO₄/H₂O₂), or a combination thereof.

In the HF etching process (S02) and the cleaning process (S03), the silicon wafer W may be dipped in a treatment solution such as an etchant, a cleaning solution, or pure water as a rinsing solution.

FIG. 2B shows a section of a SIMOX wafer obtained after the high temperature annealing process.

In the high temperature annealing process (S04), a BOX layer W4 and a SOI layer W5 are formed by subjecting the silicon wafer to heat treatment at a temperature of 1300° C. or above, preferably 1320 to 1350° C. for 6 to 20 hours under a mixture gas atmosphere with a predetermined ratio of oxygen to inert gas (for example, an oxygen partial pressure ratio of 2 to 45%), which is set as a heat treatment atmosphere.

In this embodiment, the silicon wafer is first subjected to heat treatment at a temperature of 1350° C. below, preferably a range of 1280 to 1320° C. for a predetermined period of time and then is subjected to an additional heat treatment by increasing the treatment temperature to 1350° C. or above and less than the melting point of silicon.

Specifically, the annealing process is preferably performed in an argon atmosphere (oxygen of 2%) at a temperature of 1350° C. for 5 to 10 hours after an ITOX process of 1320° C. for 10 hours.

By the annealing process, oxygen in the heat treatment atmosphere is introduced in the silicon wafer W.

At this time, since the silicon wafer W is subjected to the heat treatment under an atmosphere with oxygen concentration of 5% or more, a front surface oxide film W6 is formed as the front surface WS1 of the silicon wafer W is oxidized and a rear surface oxide film W7 is formed as the rear surface WS2 of the silicon wafer W is oxidized.

FIG. 2C shows a section of a SIMOX wafer obtained after the rear surface oxide film etching process (S15).

In the rear surface oxide film etching process (S15), only a rear surface oxide film is first etched. At this time, the rear surface oxide film W7 of the rear surface WS2 of the silicon wafer W is etched off under oxide film etching conditions of an etchant concentration of 40 to 60% HF, preferably 49% HF, an etching temperature of 40 to 60° C., preferably 60° C., and an etching time of 3 to 5 min, preferably 3 min.

In the rear surface oxide film etching process (S15), in order to treat only the rear surface WS2 of the silicon wafer W, a treatment solution is ejected on only one surface of the wafer and a single wafer etching apparatus performs a treatment while having no effect on the opposite surface.

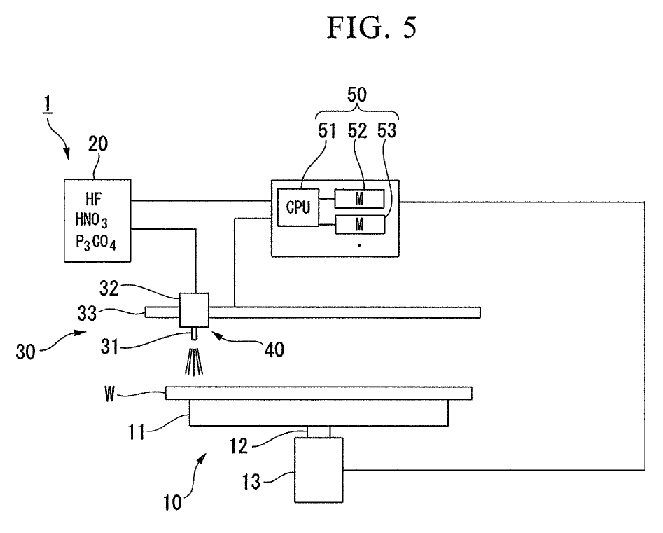

FIG. 5 is a schematic view showing a single wafer etching apparatus to perform a etching operation in the rear surface oxide film etching process according to this embodiment.

A single wafer etching apparatus 1 includes a stage 11 to support a wafer W, and a rotation driving source 13, such as a motor, which is connected to the stage 11 by a rotational axis 12 and rotationally drives the stage 11 through the rotational axis 12, both of which constitute wafer rotating means.

In addition, the single wafer etching apparatus 1 further includes etching solution supplying means 20 to supply an etching solution, a nozzle 31 to eject the etching solution supplied from the etching solution supplying means 20 on the wafer W, a nozzle base 32 to movably support the nozzle 31, and a guide 33 to regulate position/movement of the nozzle base 32. The nozzle base 32 and the guide 33 constitute nozzle position control means 30. The nozzle base 32 is provided with a mechanism to adjust an angle of the nozzle 31 with respect to the nozzle base 32, a mechanism to adjust height of an leading end of the nozzle 31 from the wafer W, and a mechanism to switch between ejection and non-ejection of the etching solution from the nozzle 31, all of which constitute ejection state control means 40.

In addition, the single wafer etching apparatus 1 further comprises a controller 50 that controls the rotation number of the rotation driving source 13 to set the rotation number of the wafer, controls the etching solution supplying means 20 to specify the supply state of the etching solution, and controls the nozzle position control means 30 and the ejection state control means 40 to set the state and position of the nozzle 31. The controller 50 includes an operation unit 51 such as a CPU, and a plurality of memory units 52, 53, . . . .

The etching solution supply means 20 supplies the nozzle 31 with an acid etching solution, particularly HF for treatment of the silicon wafer W.

In the nozzle position control means 30, the guide 33 to regulate movement of the nozzle base 32 supports the nozzle base 32 in such a manner that the nozzle 31 is movable in a radial direction of the wafer W through the rotational center of the wafer W. The guide 33 can be configured to move the nozzle base 32 in a longitudinal direction. The position of the nozzle 31 with respect to the rotational center of the wafer W can be set by movement position of the nozzle base 32 in a longitudinal direction of the guide 33. The nozzle base 32 includes a mechanism to move with respect to the guide 33 in its longitudinal direction.

In addition, one end of the guide 33 is provided to pass through the rotational center of the wafer W and the other end thereof is rotably supported in a horizontal direction. The guide 33 may be configured so that the nozzle 31 can be moved in an in-plane direction of the wafer W when the guide 33 is rotated in a horizontal direction.

The ejection state control means 40 includes angle adjustment means to adjust an angle of the nozzle 31 with respect to the nozzle base 32 provided with the nozzle base 32, height adjustment means to adjust the height of the leading end of the nozzle 31 from the wafer W, and a pair of valves to switch between ejection and non-ejection states of the etching solution from the nozzle 31. The ejection state control means 40 may switch supply of the etching solution from the etching solution supplying means 20 without providing a valve body.

In the controller 50, the memory units 52, 53, . . . store at least a shape of wafer W before being treated, position and etching state of the nozzle 31, ejection amount and etching state of the etching solution, and a standard shape of the wafer W after being treated, and the operation unit 51 calculates movement of the nozzle 31 and ejection state of the etching solution based on the stored data.

There is a possibility that oxide particles having a maximum size of 5 μm are attached to the rear surface WS2 in contact with the holder to support the wafer W in the furnace in high temperature annealing. Thus, by using the single wafer etching apparatus described above and with the etching conditions of a high concentration HF and an increased temperature of 60° C., if necessary, it is possible to completely remove the oxide particles from only the rear surface WS2 in a short amount of time. At this time, the front surface of the wafer is required to be completely protected from the etching. For example, as described above, in the single wafer etching apparatus 1 of the type to supply HF to the rear surface WS2 through the nozzle, the front surface WS1 can be protected from the etching by applying air, nitrogen (N₂) or pure water to the front surface WS1. At this time, when using air or nitrogen, it is possible to recover a chemical solution since the concentration of the chemical solution is not changed.

In the single wafer etching apparatus 1 in the rear surface oxide film etching process (S15), scrub cleaning and ultrasonic cleaning may be used as well to increase the removal efficiency of particles in addition to the HF etching and an HF-based chemical solution can be completely recovered. This allows a reduction of filthy water treatment, a reduction of working time, and a reduction of work costs, which result in an overall reduction of wafer production costs.

Upon completion of etching of the oxide film W7 of the rear surface WS2, the wafer W is turned over and then the front surface oxide film etching process (S16) is performed to etch off an oxide film of the front surface WS1.

FIG. 2D shows a section of a SIMOX wafer obtained after the front surface oxide film etching process (S16).

In the front surface oxide film etching process (S16), while the oxide film WS1 is sufficiently etched off, surface particles are sufficiently removed. In addition, a treatment condition is set which is less strict than the oxide film etching condition in the rear surface oxide film etching process (S15) such that surface defects (divots) are not expanded. Specifically, the front surface oxide film W6 of the front surface WS1 of the silicon wafer W is etched off with under oxide film etching conditions of an etchant concentration of 20 to 49% HF, preferably 49% HF, an etching temperature of 25 to 70° C., preferably 60° C., and etching time of 0.5 to 30 min, preferably 1 min. In the preferable case, throughput can be given to priority. In particular, it is preferable that, in regard to the etchant concentration, the oxide film etching condition in the front surface oxide film etching process (S16) be set less strictly than the oxide film etching condition in the rear surface oxide film etching process (S15). In addition, it is preferable that, with regard to the treatment temperature, the oxide film etching condition in the front surface oxide film etching process (S16) be set less strictly than the oxide film etching condition in the rear surface oxide film etching process (S15).

In the front surface oxide film etching process (S16), although a single wafer etching apparatus may be used like the treatment to the rear surface WS2 in the rear surface oxide film etching process (S15), since no problems occur even when the rear surface WS2 is additionally etched in the front surface oxide film etching process (S16), it is possible to use a typical single wafer double-sided etching apparatus or a batch etching apparatus of a type to immerse the wafer W in an HF etching bath (a treatment bath containing a treatment solution). If the front surface WS1 is excessively etched, surface defects (divots) appearing in the SIMOX wafer reach the BOX layer W4 from the front surface, and thus, the BOX layer W4 is melted by the HF etching, which results in an increase in the size of defects. On this account, it is necessary to find the optimal treatment time. Specifically, the HF concentration, the treatment temperature and the treatment time may be set to 20 to 49% HF, 25 to 70° C. and 0.5 to 30 min, respectively, or the amount of treatment to Si may be set with the same treatment conditions. This allows treatment to only the front surface WS1 or simultaneous treatment to both of the front and rear surfaces WS1 and WS2.

Next, in the SOI layer thickness measuring process (S07), film thickness of the SOI layer W5 is measured using a spectroscopic ellipsometer. If the film thickness is excessively large, the wafer front surface WS1 is treated by means of the above-described single wafer etching apparatus to adjust the film thickness of the SOI layer W5 to fall within a proper range. If the SOI layer W5 is too thin, then it is determined that the SOI layer W5 is unsuitable as a product and is excluded from a production line.

Finally, the cleaning process (S08) is performed with selectable conditions such as SP-1 conditions like the cleaning process (S03). Conditions in the cleaning process (S08) may be selected according to the standard of a wafer to be manufactured.

According to this embodiment, in the oxide film etching processes after the high temperature annealing process (S04), particles of the rear surface WS2 are first removed using the single wafer etching apparatus 1 under etching conditions with a sufficiently secured amount of etching (sufficient time, high HF concentration and high temperature) in the rear surface oxide film etching process (S15). Thereafter, the front surface WS1 is etched using either a single wafer etching apparatus or a batch etching apparatus under optimal etching conditions with which surface defects (divots) are not spread in the front surface oxide film etching process (S16). As a result, it is possible to manufacture a SIMOX wafer W with its front and rear surfaces WS1 and WS2 having few particles and with its front surface having a decreased size of surface defects.

Hereinafter, experimental examples related to the present invention will be described.

Experimental examples of the present invention apply the MLD method to the SIMOX process where a silicon wafer W of φ300 mm is prepared, oxygen is implanted with oxygen implantation energy of 170 KeV and a dose of 2.5×10¹⁷ cm⁻² in the oxygen implantation process (S01), thereafter, oxygen is implanted at room temperature at a dose of 2×10¹⁵ cm⁻², and then the silicon wafer W is cleaned by SP-1.

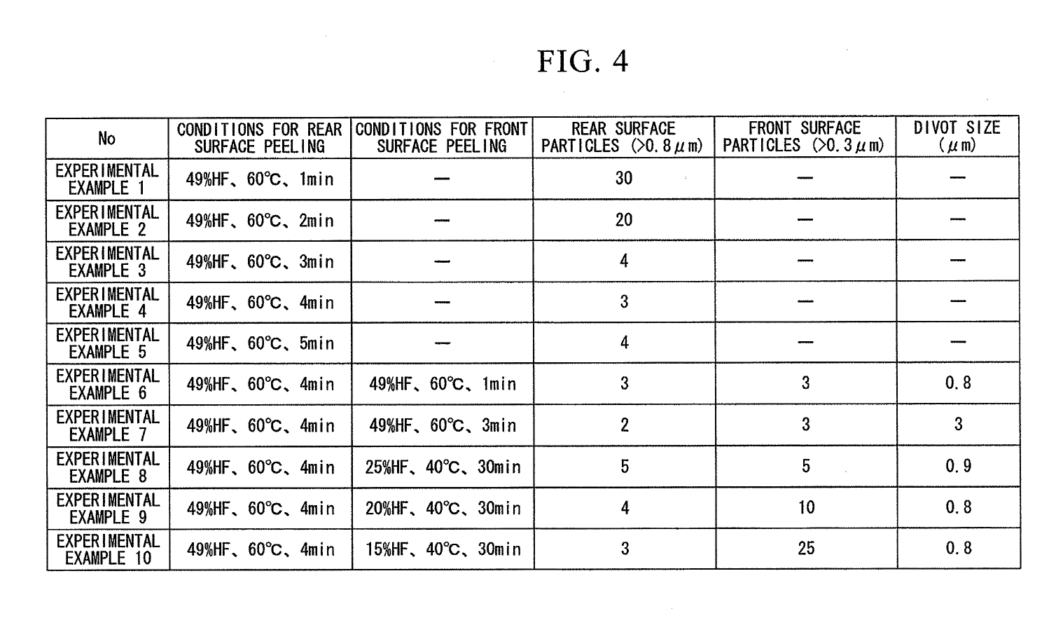

Next, the high temperature annealing process (S04) is performed in an argon atmosphere (oxygen of 2%) at a temperature of 1350° C. for 5 to 10 hours after an ITOX process of 1320° C. for 10 hours. Thereafter, the results of oxide film etching are shown in FIG. 4.

First, as Experimental Examples 1 to 5, optimal conditions for rear surface etching in the rear surface oxide film etching process (S15) are determined after treating only a rear surface and in consideration of process time. After these conditions, as Experimental Examples 6 to 10, conditions for front surface etching are optimized in the front surface oxide film etching process (S16). Rear surface particles and front surface particles are represented as the number of detected particles.

From the above results, it can be seen that the conditions shown in Experimental Example 6 are optimal. In this manner, by optimizing the front and rear surface oxide film etching conditions using the processes of the present invention, it is possible to manufacture a SIMOX wafer with a suppressed increase in size (less than 1 μm) of front surface defects (divots) and with its front and rear surfaces having few particles (less than 10).

1. A method of manufacturing a SIMOX wafer comprising an oxygen implantation step of implanting O⁺ ions in the wafer; a high temperature annealing step of forming a BOX layer in the wafer; and an oxide film etching step after the high temperature annealing step,
wherein the oxide film etching step comprises a front surface oxide film etching step to treat a front surface of the wafer at an area in which oxygen is implanted and a rear surface oxide film etching step to treat a rear surface of the wafer, and oxide film etching conditions in the front and rear oxide film etching steps are controlled differently.

2. The method of manufacturing a SIMOX wafer according to claim 1, wherein the oxide film etching step is performed with an HF-based etchant and adjusts etching time, etching temperature and etchant concentration for the front and rear surfaces independently.

3. The method of manufacturing a SIMOX wafer according to claim 1, wherein, in the oxide film etching step, the oxide film etching conditions of the front surface oxide film etching step are set less strictly than the oxide film etching conditions of the rear surface oxide film etching step.

4. The method of manufacturing a SIMOX wafer according to claim 1, wherein, in the oxide film etching step, the front surface oxide film etching step is performed after the rear surface oxide film etching step, and the rear surface oxide film etching step is performed with single wafer etching to treat only the rear surface of the wafer.

5. The method of manufacturing a SIMOX wafer according to claim 4, wherein the front surface oxide film etching step treats only the front surface of the wafer or both of the front and rear surfaces of the wafer.

6. The method of manufacturing a SIMOX wafer according to claim 2, wherein, in the oxide film etching step, scrub cleaning or ultrasonic cleaning is used to increase removal efficiency of particles in addition to the HF etching.

7. The method of manufacturing a SIMOX wafer according to claim 4, wherein, in the rear surface oxide film etching step, the front surface of the wafer is protected from the etchant by ejecting air, nitrogen (N₂) or pure water on the front surface.

8. The method of manufacturing a SIMOX wafer according to claim 4, wherein, in the rear surface oxide film etching step, the single wafer etching is performed by ejecting the etchant from a nozzle on the rear surface of the wafer rotated around the center of the wafer.

9. A SIMOX wafer manufactured using a manufacturing method according to claim 1.

10. A SIMOX wafer manufactured using a manufacturing method according to claim 2.

11. A SIMOX wafer manufactured using a manufacturing method according to claim 3.

12. A SIMOX wafer manufactured using a manufacturing method according to claim 4.

13. A SIMOX wafer manufactured using a manufacturing method according to claim 5.

14. A SIMOX wafer manufactured using a manufacturing method according to claim 6.

15. A SIMOX wafer manufactured using a manufacturing method according to claim 7.

16. A SIMOX wafer manufactured using a manufacturing method according to claim 8.
